(19) United States
(12) Patent Application Publication
(10) Pub. No.: US 2026/0144167 A1
(43) Pub. Date: May 21, 2026

(54) SEMICONDUCTOR PACKAGE AND METHODS OF FORMING THE SAME

(71) Applicant: TAIWAN SEMICONDUCTOR MANUFACTURING COMPANY, LTD., Hsinchu (TW)

(72) Inventors: Tzu Jung TIEN, Hsinchu (TW); Jen-Yuan CHANG, Hsinchu (TW)

(21) Appl. No.: 18/954,628

(22) Filed: Nov. 21, 2024

(51) Int. Cl. H01L 23/498; H01L 21/768

(52) U.S. Cl. CPC H10W 90/701; H10W 20/043; H10W 70/69

(57) ABSTRACT

A semiconductor package and methods of forming the same are provided. The method includes depositing a bonding layer, forming a first opening in the bonding layer, depositing a conductive layer on exposed surfaces of the first opening, and forming a second opening extending from a bottom of the first opening. The second opening has a smaller dimension than a dimension of the first opening. The method further includes depositing a barrier layer on exposed surfaces of the first opening and the second opening and performing an electrochemical plating process to fill the first opening and the second opening with a metal layer.

### BACKGROUND

As the semiconductor industry introduces new generations of integrated circuits (IC) having higher performance and more functionality, the density of the elements forming the ICs increases, while the dimensions, sizes and spacing between components or elements are reduced. To support the miniaturization device with increased number of circuits built on tighter space, smaller packages that occupy less area than previous packages is required. Various types of packages such as quad flat pack (QFP), pin grid array (PGA), ball grid array (BGA), flip chips (FC), three-dimensional integrated circuits (3D ICs), wafer-level packages (WLPs), and package on package (PoP) devices have been developed. Front-end 3D inter-chip stacking technologies are used for re-integration of chiplets partitioned from System on Chip (SoC). The resulting integrated chip outperforms the original SoC in system performance. It also provides the flexibility to integrate additional system functionalities. Advantages of those advanced packaging technologies like 3D inter-chip stacking technologies include improved integration density, faster speeds, and higher bandwidth because of the decreased length of interconnects between the stacked chips. However, there are quite a few challenges to be handled for the technologies of advanced packaging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional diagram illustrating an example semiconductor package in accordance with some embodiments.

FIG. 2 is an enlarged cross-sectional view of a bonding metal pad of a die to be bonded with a bonding metal pad of another die according with some embodiments.

FIGS. 3A, 3B, 3C, 3D, 3E, and 3F are cross-sectional views of a bonding metal pad of a die to be bonded with a bonding metal pad of another die.

FIGS. 4A and 4B are top views of a bond pad metal (BPM) and a bond pad via (BPV) of a bonding metal pad of a die to be bonded with a bonding metal pad of another die.

FIGS. 5A, 5B, 5C, 5D, 5E, 5F, and 5G are cross-sectional views of a bonding metal pad of a die to be bonded with a bonding metal pad of another die.

### DETAIL DESCRIPTOIN

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Some of the features described below can be replaced or eliminated and additional features can be added for different embodiments. Although some embodiments are discussed with operations performed in a particular order, these operations may be performed in another logical order.

Packaging technologies were once considered just back-end processes without significance. However, applications such as cloud computing, big data analytics, artificial intelligence (AI), neural network training, AI inferencing, mobile computing on advanced smartphones, and even self-driving cars are all pushing further development of the computing technologies, and thus creating increased modern workloads that brings packaging technologies to the forefront of innovation. The packaging technologies are critical to a product's performance, function, and cost.

Chip-on-Wafer-on-Substrate is a wafer-level multi-chip packaging technology often used in conjunction with bonding of dielectric layers and conductive features. For example, Chip-on-Wafer-on-Substrate is a packaging technology that incorporates multiple chips side-by-side on a silicon interposer in order to achieve better interconnect density and performance. Individual chips are bonded through, for example, micro-bumps on a silicon interposer, forming a chip-on-wafer (CoW) structure. The CoW structure is then subsequently thinned such that through-silicon-vias (TSVs) are exposed, which is followed by the formation of bumps (e.g., C4 bumps) and singulation. The CoW structure is then bonded to a package substrate forming the Chip-on-Wafer-on-Substrate structure. Since multiple chips or dies are generally incorporated in a side-by-side manner, the Chip-on-Wafer-on-Substrate is considered a 2.5-dimensional (2.5D) wafer-level packaging technology.

On the other hand, those multiple chips that are bonded to the interposer in a Chip-on-Wafer-on-Substrate structure can each include stacking dies or chiplets (i.e., modular dies), with multi-layers, multi-chip sizes, and multi-functions. In one implementation, the stacking dies are bonded together by bonding dielectric layers and bonding conductive features in the dielectric layers. No bumps like micro-bumps are used, and this type of bonding can provide improved integration density, faster speeds, and higher bandwidth. In addition to die-to-die bonding, this type of bonding can also be used for wafer-to-wafer bonding and die-to-wafer bonding. In another implementation, the stacking dies are bonded together using fusion bonding.

Stacking dies featuring bumpless ultra-high-density-vertical stacking is sometimes referred to as System on Integrated Chips (SoIC) technologies. SoIC technologies can achieve high performance, low power, and minimum resistance-inductance-capacitance (RLC). SoIC technologies integrate active and passive chips that are partitioned from System on Chip (SoC), into a new integrated SoC system, which is electrically identical to native SoC, to achieve better form factor and performance. A die stack bonded together is sometimes referred to as a SoIC die stack (“SoIC die stack” and “die stack” are used interchangeably throughout the disclosure).

On the other hand, even though two dies are bonded together, a package including the SoIC die stack comprised of those two dies may still have interfaces between two dielectric layers. One example of such dielectric-to-dielectric bonding interfaces occurs when a top die and a dummy die are both bonded to a bottom die that has a larger size than the top die. The dummy die is used to fill the size gap between the bottom die and the top die, making the structure of the package more stable. Although the top die and the bottom die are bonded by bonding dielectric layers and conductive features, the dummy die and the bottom die are bonded using a dielectric-to-dielectric bonding technique (like fusion bonding) because there is no need for metal-to-metal interconnects between the bottom die and the dummy die. The dielectric-to-dielectric bonding interface between the dummy die and the bottom die is located at the same horizontal plane as the bonding interface between the top die and the bottom die.

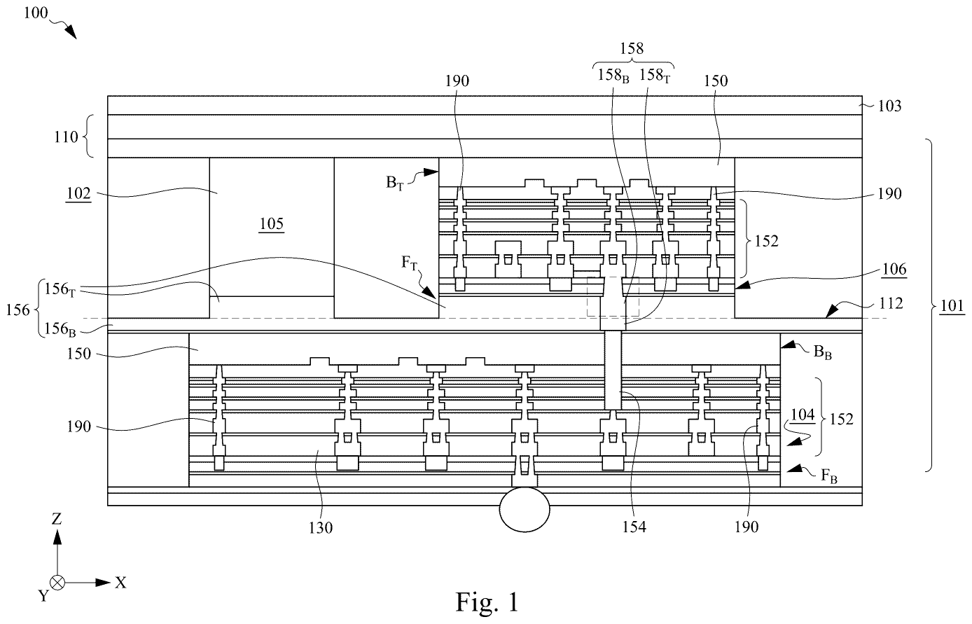

FIG. 1 is a cross-sectional diagram illustrating an example semiconductor package 100 in accordance with some embodiments. In the example shown in FIG. 1, the semiconductor package 100 includes, among other things, a SoIC die stack 101 and a dummy die 102. Thus, the semiconductor package 100 is a SoIC package. The SoIC die stack 101 includes a bottom die 104 and a top die 106. The bottom die 104 has a front side F_{B} (“B” stands for the “bottom” die in FIG. 1) and a back side B_{B}. In the example shown in FIG. 1, the bottom die 104 has been flipped upside down. The top die 106 has a front side F_{T} (“T” stands for the “top” die 106 in FIG. 1) and a back side B_{T}. In the example shown in FIG. 1, the top die 106 has also been flipped upside down. The front side F_{T} of the top die 106 is bonded to the back side B_{B} of the bottom die 104 by bonding dielectric layers and conductive features in the example shown in FIG. 1, details of which will be described below.

The dummy die 102 is bonded to the back side B_{B} of the bottom die 104 (lateral to the top die 106) using dielectric-to-dielectric bonding in the example shown in FIG. 1, details of which will be described below. In the example shown in FIG. 1, the top die 106 has a smaller size, in a first horizontal direction and a second horizontal direction (i.e., the X-direction and the Y-direction shown in FIG. 1) than the bottom die 104. That is, the bottom surface of the top die 106 has a smaller area than that of the top surface of the bottom die 104. Thus, the dummy die 102 is introduced to bridge the horizontal dimension gap between the bottom die 104 and the top die 106.

In the example shown in FIG. 1, the back side B_{T} of the top die 106 and the top surface of the dummy die 102 are both bonded to a carrier wafer 103, which has been processed using thinning processes (e.g., silicon grinding) and planarization processes (e.g., chemical-mechanical polishing (CMP)). A redistribution (RLD) structure 110 may be disposed between the back side B_{T} of the top die 106 and the carrier wafer 103. The redistribution structure 110 may comprise a dielectric that includes a single-layer or a multi-layer dielectric layers. The redistribution structure 110 may include conductive or metal features (not shown) disposed therein to interconnect the metal or conductive structures in the SoIC die stack 101.

A bonding layer 156, including a bottom bonding layer 156_{B} formed on a silicon substrate 150 of the bottom die 104 at the back side B_{B} and a bonding layer 156_{T} on the top surface of the top die 106 at the front side F_{T}. In one embodiment, the bonding layer 156 is made of a dielectric and can be used for bonding the top die 106 with the bottom die 104. In one implementation, the bonding layers 156_{B} and 156_{T} are made of silicon dioxide. In another embodiment, the bonding layers 156_{B} and 156_{T} are made of silicon oxynitride. It should be understood that these examples are not intended to be limiting, and other silicon-containing dielectric materials may be employed in other examples.

One or more semiconductor devices (e.g., transistors, resistors, capacitors, inductors, etc.) are formed on the silicon substrate 150 before being flipped in a front-end-of-line (FEOL) process. A multilayer interconnect (MLI) structure 152 is disposed over the one or more semiconductor devices before the top die 106 is flipped. The MLI structure 152 includes a combination of dielectric layers and conductive layers configured to form various interconnect structures. The conductive layers are configured to form vertical interconnect features (e.g., device-level contacts, vias, etc.) and horizontal interconnect features (e.g., conductive lines extending in a horizontal plane). Vertical interconnect features typically connect horizontal interconnect features in different layers of the MLI structure 152. During operation of the bottom die 104, the interconnect features are configured to route signals and/or distribute signals (e.g., clock signals, voltage signals, ground signals) to the one or more semiconductor devices to fulfill certain functions. Although the MLI structure 152 is depicted in FIG. 1 with a given number of dielectric layers and conductive features, the present disclosure contemplates MLI structures having more or fewer dielectric layers and/or conductive layers depending on design requirements of the bottom die 104.

A seal ring 190 is a metallization structure that is located between and separates the core circuitry of the bottom die 104 and the peripheral regions (or edges) of the bottom die 104. The seal ring 190 surrounds the core circuitry in the X-Y plane and prevents the intrusion of cracks and moisture penetration or chemical damage like acid, alkaline containing or diffusion of contaminating species.

In the example shown in FIG. 1, the bottom die 104 includes a bonding metal pad 158_{B} formed in the bottom bonding layer 156_{B}. The bonding metal pad 158_{B} is connected to the MLI structure 152 through a through-silicon via (TSV) 154, which penetrates the silicon substrate 150 in the vertical direction (i.e., the Z-direction). Although only one bonding metal pad 158_{B} and a TSV 154 is shown in FIG. 1, more than one bonding metal pad 158_{B} and TSV 154 may be formed as desired. According to some embodiments, many bonding metal pads 158_{B} and corresponding TSVs 154 with small critical dimensions and pitches may be formed to achieve better interconnect density and performance (e.g., faster speeds, higher bandwidth, and the like). The bonding metal pad 158_{B} may be made of copper.

As shown in FIG. 1, the top die 106 has a top bonding layer 156_{T} formed at the front side of the top die 106 and over an MLI structure 152 before the top die 106 is flipped. In one implementation, the top bonding layer 156_{T} is made of a dielectric and can be used for bonding with the bottom bonding layer 156_{B}, as mentioned above. Likewise, the top die 106 includes a bonding metal pad 158_{T} formed in the top bonding layer 156_{T}, and the bonding metal pad 158_{T} is connected to the MLI structure 152 through, for example, a via. It should be understood that although only one bonding metal pad 158_{T} is shown in FIG. 1, this is not intended to be limiting. In other examples, there are many bonding metal pads 158_{T}, with small critical dimensions and pitches, thus achieving better interconnect density and performance (e.g., faster speeds, higher bandwidth, and the like). In one implementation, the bonding metal pad 158_{T} is made of copper. As such, a copper-to-copper interconnect is formed between the bottom die 104 and the top die 106 using the bonding metal pads 158_{B} and 158_{T}.

One or more semiconductor devices (e.g., transistors, resistors, capacitors, inductors, etc.) are formed on the silicon substrate 150 of the top die 106, before being flipped, in a FEOL process. The MLI structure 152 is disposed over the one or more semiconductor devices before being flipped. Similarly, a seal ring 190 is located between and separates the core circuitry of the top die 106 and the peripheral regions (or edges) of the top die 106. The seal ring 190 surrounds the core circuitry in the X-Y plane and prevents the intrusion of cracks and moisture penetration or chemical damage like acid, alkaline containing or diffusion of contaminating species.

The dummy die 102 includes a bulk silicon 105 and a top bonding layer 156_{T′}formed at the bottom surface of the bulk silicon 105. The top bonding layer 156_{T}′ is made of a dielectric and can be used for bonding with the bottom bonding layer 156_{B} at the bottom die 104, as mentioned above. Instead of placing the dummy die 102, an additional functional die may be placed in parallel with the top die according to some embodiments. The interconnections between the additional die and the bottom die 104 may be established by the bonding structure between the top die 106 and the bottom die 104.

While providing many advantages, including allowing advanced 3D device stacking, higher input/output (I/O), smaller bonding pitch, higher memory density, expanded bandwidth, higher power, and speed efficiency, SoIC bonding often suffers from unstable interface resistance, which ultimately affects the performance of the 3D device. The resistance instability may arise from voids created during production of the bonding structure between a top die and a bottom die. For example, the voids may be created during operations for forming the bonding metal pad 158_{T} within the top bonding layer 156_{T} as shown in FIG. 1.

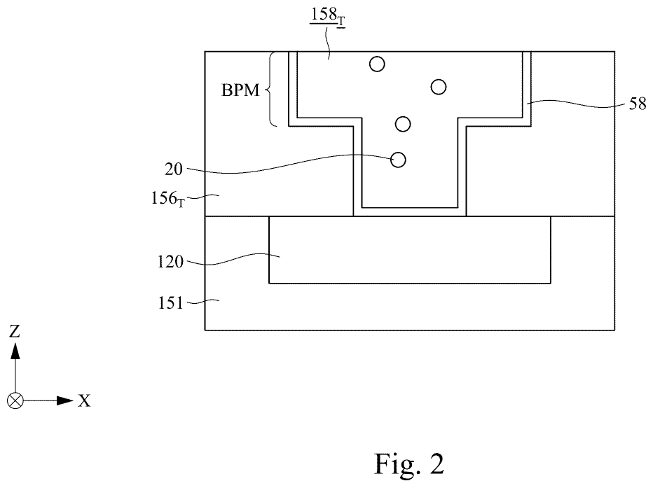

FIG. 2 provides an enlarged cross-sectional view of the top bonding metal pad 158_{T} formed between the front side F_{T} of the top die 106 and the back side B_{B} of the bottom die 104. In FIG. 2, the top bonding metal pad 158_{T} is flipped from the orientation as shown in FIG. 1. The bonding metal pad 158_{T} may include a bond pad metal (BPM) to interconnect with the conductive features of the bottom die 104 and a bond pad via (BPV) to connect with a redistribution layer 120 formed in a dielectric layer 151 of the top die 106. A barrier layer 58 may be formed prior to the electrochemical plating process for forming the bonding metal pad 158_{T}. During the electrochemical plating (ECP) of the BPM and/or BPV, a high concentration of accelerator molecules may be present at the bottom of the trench or via while suppressors may absorb to the sidewall and serve to suppress Cu deposition on the sidewall of the trench or via to enable the bottom-up filling. Leveler may be placed at the top surface of the bonding metal pad 158_{T} to slow over-plating and to give a smooth deposit for easy chemical mechanical planarization (CMP). The large linewidth of the BPM, for example, a linewidth larger than that of the conductive features formed in the MLI structure 152, may result in a mismatch of the concentrations of the suppressors absorbing to the sidewall and the accelerators placed at the bottom; and consequently, causes a mismatch of electroplating speed at the sidewall and at the bottom of the trench or via intended for forming the hybrid bonding metal pads. The mismatch in ECP speed may create voids 20 in both the BPV and BPM.

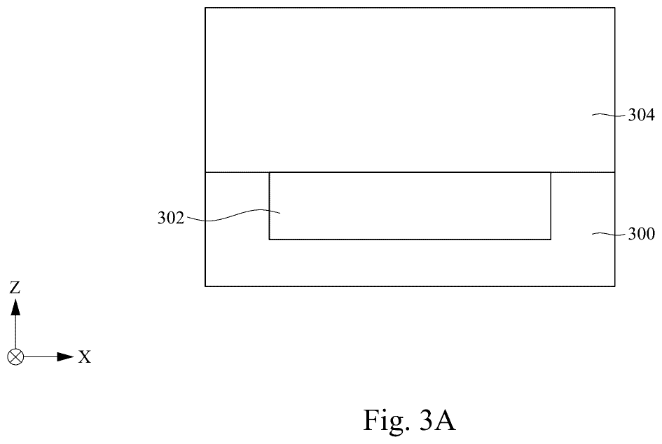

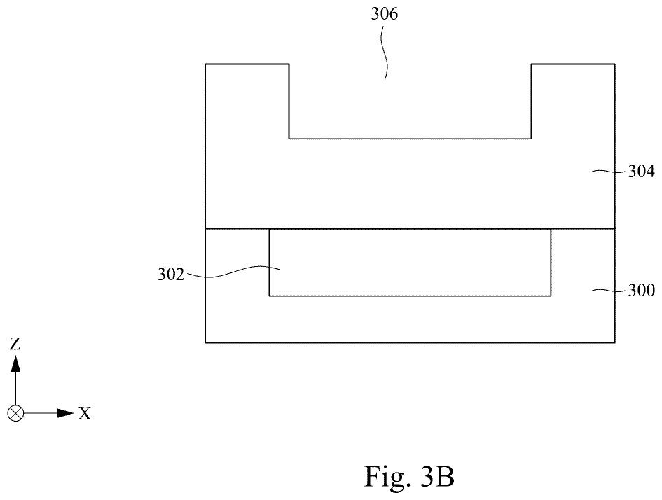

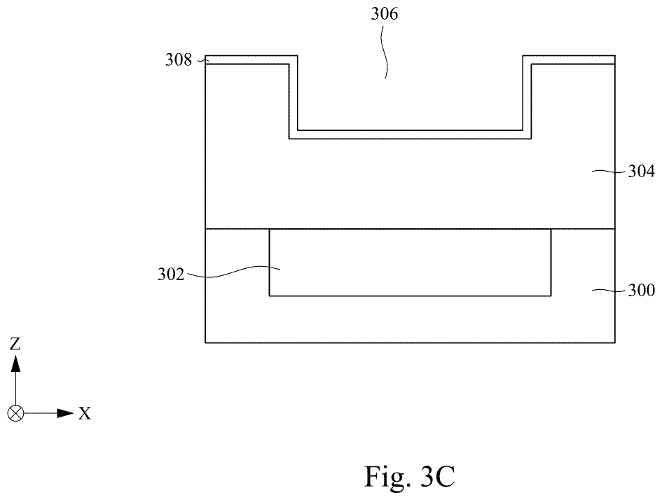

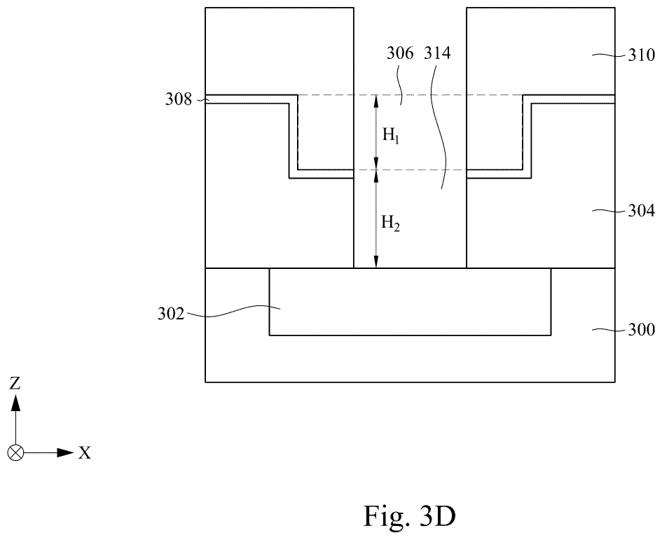

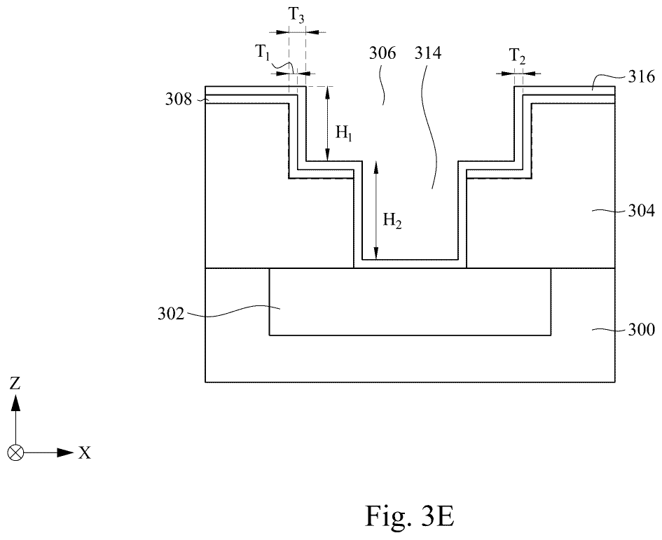

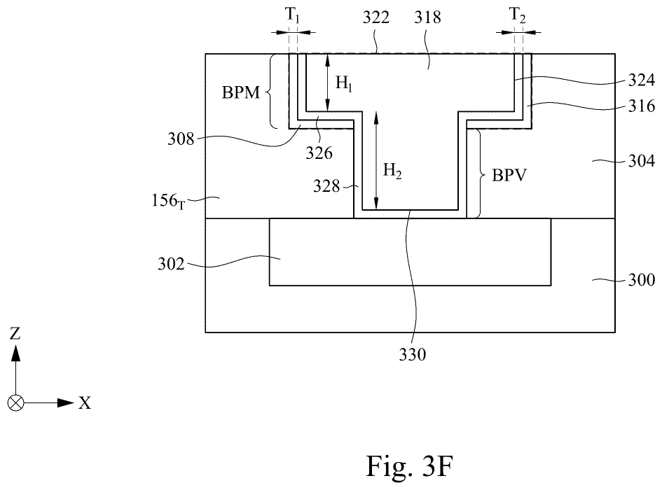

FIGS. 3A to 3F are cross-sectional views of a bonding structure formed at various stages of a fabrication process that eliminates or suppresses formation of voids according to one embodiment. In FIG. 3A, a bonding layer 304 is formed on a dielectric layer 300, in which a redistribution layer (RDL) 302 is formed therein. The dielectric layer 300 and the RDL 302 may be formed over an interconnect structure (not shown), such as a MLI, and the MLI may be formed over a substrate (not shown). The substrate may be similar to the silicon substrate 150 of the top die 106 as shown in FIG. 1. The bonding layer 304 includes a dielectric layer made of a SiO₂ layer, a SiCN layer, or other similar dielectric layer by plasma enhanced chemical vapor deposition (PECVD) process or other suitable process. The bonding layer 304 may be similar to the top bonding layer 156_{T} of the top die 106 as shown in FIG. 1.

In FIG. 3B, a portion of the bonding layer 304 is removed to form an opening 306 in which a BPM is to be formed in subsequent processes. Therefore, an opening 306 is formed to extend through an upper portion of the bonding layer 304 and aligned with the underlying RDL 302. The opening 306 does not penetrate through the lower portion of bonding layer 304, nor does it expose the underlying RDL 302, at the fabrication stage shown in FIG. 3B. In FIG. 3C, a conductive layer 308 is formed on the exposed surface of the bonding layer 304. The conductive layer 308 may be formed from Ti, TiN, Ta, TaN, or other conductive materials to enhance conductivity and reduce resistance during the electrochemical plating process performed subsequently. The conductive layer 308 may be formed by physical vapor deposition (PVD) with a thickness T₁ of about 50 Å to about 150 Å. Other processes such as atomic layer deposition (ALD) may also be used for forming the conductive layer 308. When the conductive layer 308 is formed by a PVD process, the thickness at the sidewall of the opening 306 tends to be thinner than that formed at the bottom of the opening 306. With the thinner conductive layer 308 at the sidewall than the bottom of the opening 306, the concentration of accelerators may be adjusted during the subsequently performed electrochemical plating process to enhance the plating efficiency. In some embodiment, a re-sputtering process may be applied to allow the conductive layer 308 formed at the bottom to be sputtered and re-deposited on the sidewall of the opening 306. The increased thickness of conductive layer 308 on the sidewall of the opening 306 reduces the resistance and increases a downward current flow during the subsequent electrochemical plating process. Thus, in some embodiments, the conductive layer 308 is a conformal layer. The term “conformal” may be used herein for ease of description upon a layer having substantial same thickness over various regions. In some embodiments, the conductive layer 308 may be formed by depositing a conductive layer using PVD and then re-sputtering the conductive layer so the bottom portion and sidewall portion of the conductive layer 308 have substantially the same thickness. In some embodiments, the conductive layer 308 is deposited by a conformal process, such as ALD.

In FIG. 3D, a photoresist layer 310 layer is formed over the conductive layer 308 and fills the opening 306. The photoresist layer 310 is then patterned to expose a portion of the conductive layer 308 within the opening 306. The exposed portion of the conductive layer 308 is then removed to expose a portion of the bonding layer 304. Next, the exposed portion of the bonding layer 304 is removed to form an opening 314 under the opening 306 to expose the underlying RDL 302. The opening 314 has a linewidth smaller than the opening 306 along the X direction. In some embodiments, the opening 314 has a length smaller than the opening 306 along the Y direction. In some embodiments, the opening 306 is a trench, and the opening 314 is a via opening. The heights of the openings 306 and 314 are denoted as H₁ and H₂, respectively.

The photoresist layer 310 is then removed as shown in FIG. 3E, and a barrier layer 316 is then conformally formed to cover the conductive layer 308, the sidewall of the opening 314, and the bottom surface of the opening 314, that is, the exposed surface of the RDL 302. The barrier layer 316 may be made of a material that blocks diffusion of metal, such as copper, into the bonding layer 304 and provides a sufficient adhesion to the materials for forming both the BPM and BPV formed in the subsequent ECP process. To improve the efficiency of the electrochemical plating process, electrically conductive materials such as TaN, TiN, Ta, AlN or other conductive material may be selected for forming the barrier layer 316. The barrier layer 316 may also be a Ta/TaN composite layer according to some embodiment.

In one embodiment, the barrier layer 316 has a thickness T₂ smaller than the thickness T₁ of the conductive layer 308. In other embodiments, the thickness T₂ of the barrier layer 316 may be larger than or equal to the thickness T₁ of the conductive layer 308. The formation of the conductive layer 308 allows the thickness of conductive materials at the sidewall of the opening 306 always thicker than that at the sidewall of the opening 314. However, the combined thickness T₃ is smaller than both H₁ and H₂. In some embodiments, the linewidths of the opening 306 and 314 are about 2 μm and about 1 μm, respectively, the thickness T₁ may be about 50 Å to about 150 Å, and the thickness T₂ may be about 400 Å to about 600 Å, such that the combined thickness T₃ of the conductive layer 308 and the barrier layer 316 at the sidewall of the opening 306 may be less than about 750 Å.

An electrochemical plating (ECP) process is then performed to fill the opening 306 and the opening 314 with a metal layer 318 made of material such as Cu, as shown in FIG. 3F. Before the ECP process, a seeding layer (not shown), such as Cu seeding layer, may be deposited on the exposed surfaces of the openings 306 and 314. The upper portion of the metal layer 318 filling the opening 306 is referred to as BPM and the lower portion of the metal layer 318 filling the opening 314 is referred to as BPV. The combined thickness T₃ at the sidewall of the opening 306 is thicker than the thickness T₂ at the sidewall of the opening 314. As a result, the resistance during the electrochemical plating process is reduced, thus allowing more current to flow down to the bottom of the opening 314, such that the plating efficiency is enhanced, and formation of voids can be significantly reduced or eliminated. The void-free metal layer 318 leads to reduced electrical resistance during the operation of the SoIC package. The metal layer 318 may be also formed on the bonding layer 304, and a planarization process, such as a chemical mechanical polishing (CMP) process, may be performed to remove the portion of the metal layer 318 formed on the bonding layer 304. The portions of the conductive layer 308 and the barrier layer 316 formed on the bonding layer 304 may be also removed by the planarization process. As a result, in some embodiments, the top surface of the metal layer 318 and the top layer of the bonding layer 304 may be substantially coplanar.

In some embodiments, as shown in FIG. 3F, the BPM of the metal layer 318 includes a top surface 322, a side surface 324 connected to the top surface 322, and a bottom surface 326 connected to the side surface 324. In some embodiments, a first portion of the barrier layer 316 is disposed adjacent the side surface 324 and the bottom surface 326, and the conductive layer 308 is disposed adjacent the first portion of the barrier layer 316. The bonding layer 304 is disposed adjacent the conductive layer 308. In some embodiments, the first portion of the barrier layer 316 is in contact with the side surface 324 and the bottom surface 326, the conductive layer 308 is in contact with the first portion of the barrier layer 316, and the bonding layer 304 is in contact with the conductive layer 308. The BPV of the metal layer 318 has a side surface 328 and a bottom surface 330 connected to the side surface 328, as shown in FIG. 3F. In some embodiments, a second portion of the barrier layer 316 is disposed adjacent the side surface 328, and the bonding layer 304 is disposed adjacent the second portion of the barrier layer 316. In some embodiments, the second portion of the barrier layer 316 is also disposed adjacent and in contact with a side surface of the conductive layer 308, as shown in FIG. 3F. A third portion of the barrier layer 316 may be disposed between the bottom surface 330 and the RDL 302, as shown in FIG. 3F. In some embodiments, the second portion of the barrier layer 316 is in contact with the side surface 328, and the bonding layer 304 is in contact with the second portion of the barrier layer 316. In some embodiments, the third portion of the barrier layer 316 is in contact with the bottom surface 330 and the RDL 302, as shown in FIG. 3F.

In the embodiments as shown in FIGS. 3A to 3F, the conductive layer 308 and the barrier layer 316 may be made of the same material, such as Ti, TiN, Ta, or TaN. Alternatively, the conductive layer 308 and the barrier layer 316 may be made of different materials. In some embodiments, the conductive layer 308 is made of Ti, and the barrier layer 316 is made of Ta (or TaN). The combined thickness T₃ of the conductive layer 308 and the barrier layer 316 formed on the sidewall of the opening 306 is thicker than the thickness of the barrier layer 316 formed on the sidewall of the opening 314.

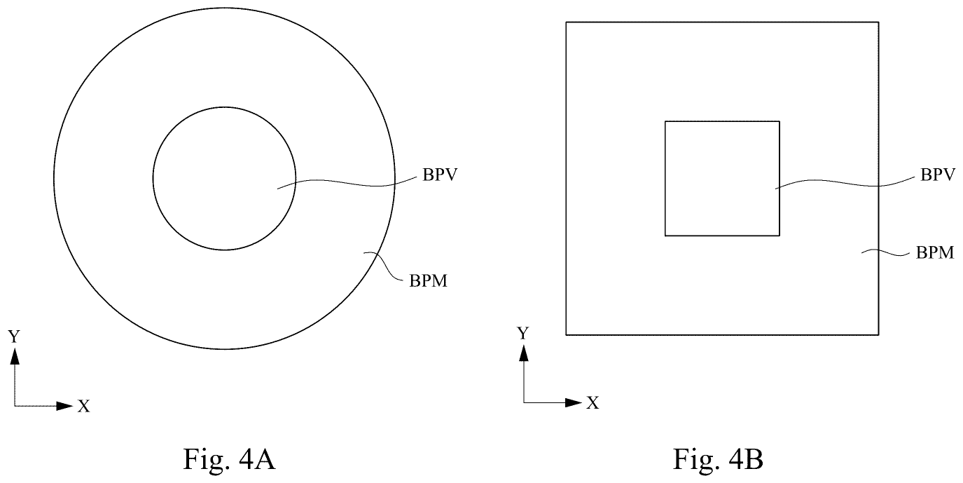

FIGS. 4A and 4B show the top views of the BPM and BPV. In one embodiment, the BPM and BPV have circular cross sections along the X-Y planes as shown in FIG. 4A. In another embodiment, the cross sections of the BPM and BPV along X-Y plane may be rectangular as shown in FIG. 4B. In other embodiments, the BPM and BPV may be formed with other shapes, for example, oval, regular polygonal, or irregular polygonal.

In some embodiments, the metal layer 318 is the bonding metal pad 158_{T} shown in FIG. 1. The metal layer 318, the bonding layer 304, the MLI located below the bonding layer 304, and the substrate located below the MLI may form a die, such as the top die 106 shown in FIG. 1. The die including the metal layer 318 may be flipped over and then bonded to another die, such as the bottom die 104 shown in FIG. 1.

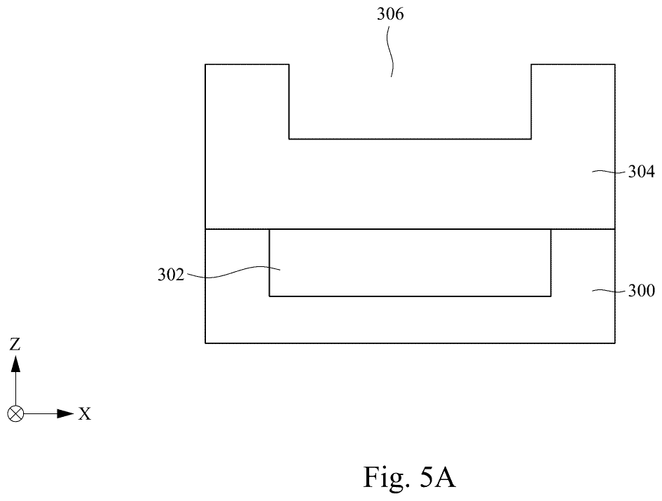

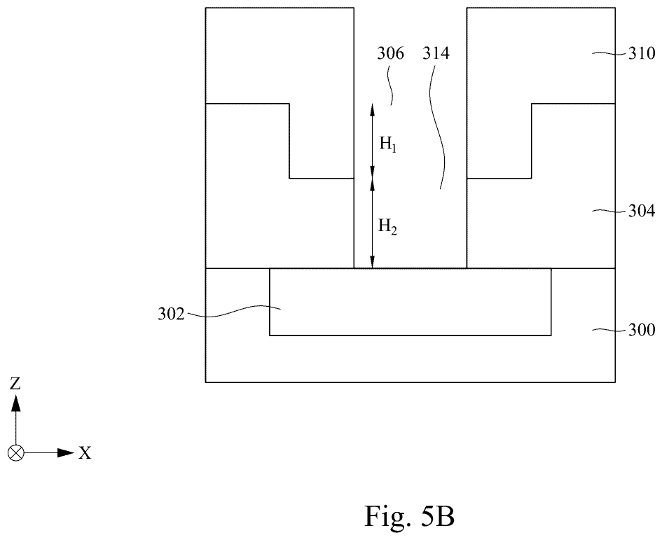

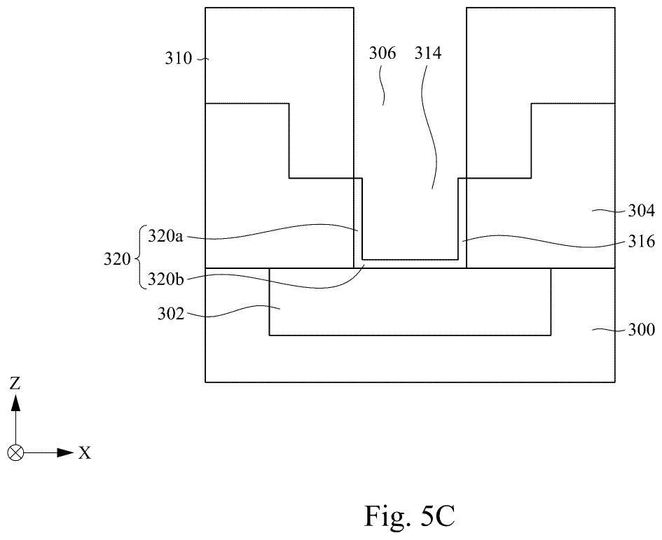

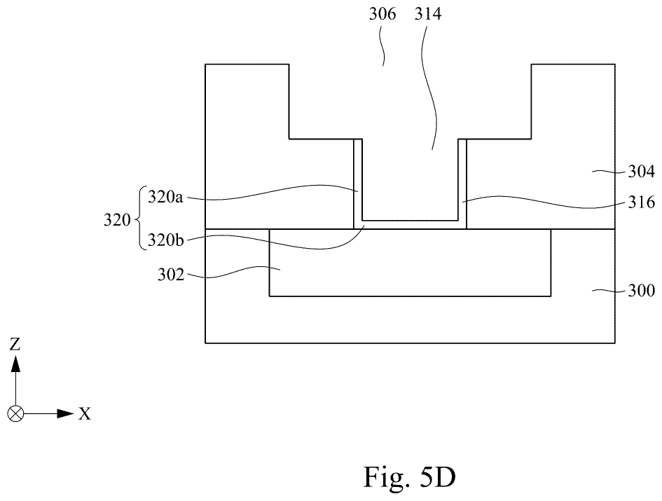

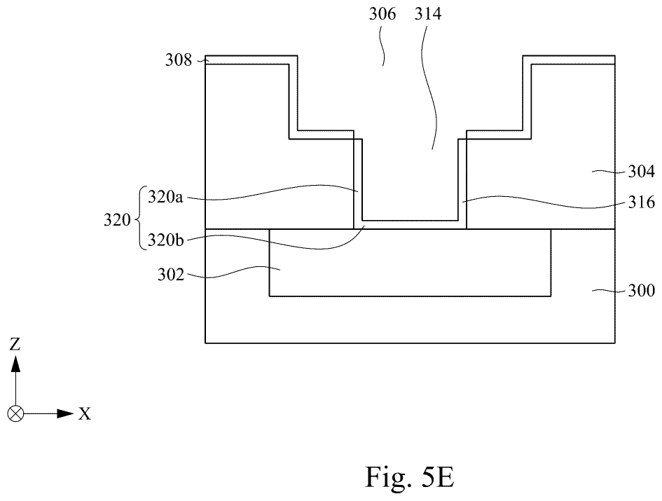

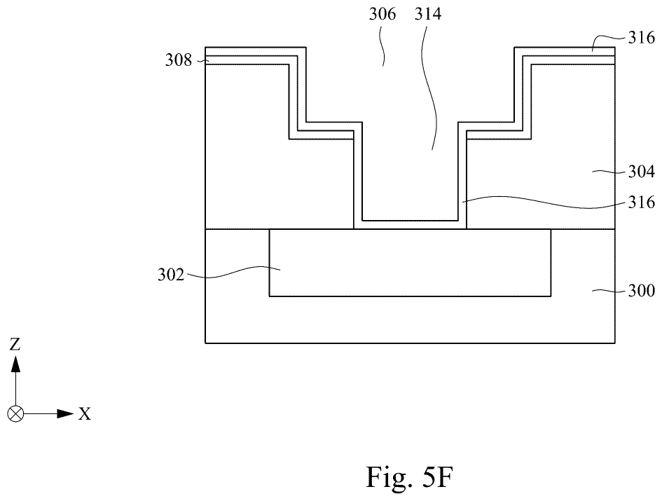

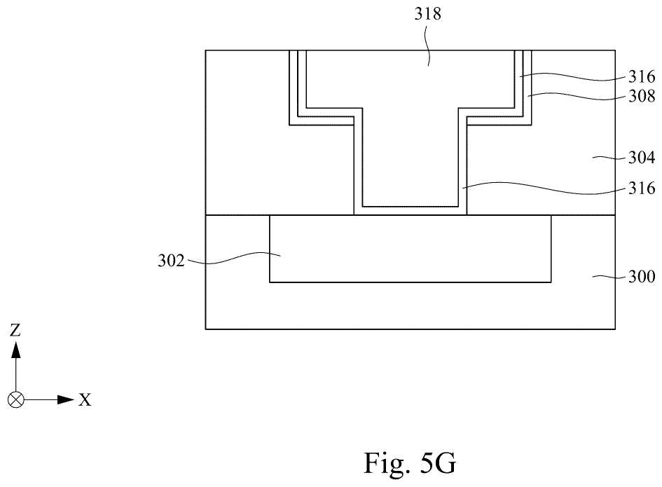

FIGS. 5A-5G are cross-sectional views of a bonding structure formed at various stages of a fabrication process that eliminates or suppresses the formation of voids in a metal layer, in accordance with some embodiments. As shown in FIG. 5A, the opening 306 is formed in the bonding layer 304. The bonding layer 304 is formed over the dielectric layer 300, and the RDL 302 is formed in the dielectric layer 300. As shown in FIG. 5B, the photoresist layer 310 is formed on the bonding layer 304, and opening 314 is formed in the photoresist layer 310 and the bonding layer 304. A portion of the opening 306 is filled with the photoresist layer 310. The opening 306 has the height H₁, and the opening 314 has the height H₂.

As shown in FIG. 5C, a blocking layer 320 is formed on the sidewall and the bottom of the opening 314. The blocking layer 320 may be selectively formed on the materials of the RDL 302 and the bonding layer 304. The blocking layer 320 is not formed on the photoresist layer 310. In some embodiments, the blocking layer 320 includes a first layer 320a formed on the sidewall of the bonding layer 304 and a second layer 320b formed on the RDL 302. The first layer 320a may be selectively formed on the bonding layer 304, and not on the RDL 302 and the photoresist layer 310. The first layer 320a may include a self-assembled monolayer (SAM) having a head group and a tail group. The head group shows a specific affinity for the material of the bonding layer 304, thus the head group is adsorbed onto the sidewall of the bonding layer 304. The tail group inhibits the adsorption of the precursors of the conductive layer 308 (FIG. 5E) during subsequent processes. The second layer 320b is selectively deposited on the RDL 302, and not on the bonding layer 304 and the photoresist layer 310 due to the specific affinity of the head group of the second layer 320b to the material of the RDL 302. The second layer 320b may include a SAM having a head group and a tail group. Similar to the first layer 320a, the head group of the second layer 320b shows a specific affinity for the material of the RDL 302, thus the head group is adsorbed onto the RDL 302. The tail group of the second layer 320b inhibits the adsorption of the precursors of the conductive layer 308 (FIG. 5E) during subsequent processes. In some embodiments, the head group of the second layer 320b includes a silane group, a phosphonate group, an amine group, a thiol group, a disulfide group, a carboxyl group, the like, or a combination thereof. The tail group of the second layer 320b may include an alkyl chain, such as a linear alkyl chain or a branched alkyl chain. In some embodiments, the second layer 320b includes n-alkanethiols (e.g., dodecanethiol, octadecanethiol (ODT), or the like), aromatic thiols (e.g., benzenethiol), phosphonic acid (e.g., octadecylphosphonic acid (ODPA)), n-alkanoic acid (e.g., acetic acid), the like, or a combination thereof. During the deposition of the conductive layer 308 (FIG. 5E), the tail group of the first and second layers 320a, 320b inhibits the adsorption of the precursors of the conductive layer 308. Thus, the conductive layer 308 is not formed on the blocking layer 320. The blocking layer 320 is removed after the formation of the conductive layer 308. The removal of the blocking layer 320 may be a selective etch process that does not substantially affect the conductive layer 308 and the bonding layer 304.

The first and second layers 320a, 320b may be formed at different times or at the same time. Because the head groups of the first and second layers 320a, 320b show specific affinity for the bonding layer 304 and the RDL 302, respectively, a single process may be performed to form the first and second layers 320a, 320b.

Next, as shown in FIG. 5D, the photoresist layer 310 is removed, and the opening 306 is exposed. As shown in FIG. 5E, the conductive layer 308 is selectively deposited on the sidewall and bottom of the opening 306. The blocking layer 320 prevents the conductive layer 308 from being deposited on the sidewall and bottom of the opening 314. After the selective deposition of the conductive layer 308, the blocking layer 320 is removed. In some embodiments, the first and second layers 320a, 320b are removed at the same time, such as by a single etch process. In some embodiments, the first and second layers 320a, 320b are removed at different times, such as by two etch processes. In some embodiments, the bonding layer 304 and the RDL 302 are not substantially affected by the process(es) to remove the first and second layers 320a, 320b of the blocking layer 320. In some embodiments, the process(es) to remove the blocking layer 320 also removes portions of the bonding layer 304 and/or the RDL 302. For example, the bonding layer 304 may be laterally recessed so width of the opening 314 may be enlarged, and the RDL 302 may be recessed along the Z direction such that a top surface of the RDL 302 exposed in the opening 314 is located at a level below a top surface of the RDL 302 in contact with the bonding layer 304. Next, as shown in FIG. 5F, the barrier layer 316 is deposited on the conductive layer 308 in the opening 306 and on the bonding layer 304 and the RDL 302 in the opening 314. As described above, the combined thickness T₃ of the conductive layer 308 and the barrier layer 316 in the opening 306 is greater than the thickness T₂ of the barrier layer 316 in the opening 314. As a result, the subsequent ECP process to form the metal layer 318 can be performed without forming voids in the metal layer 318. As shown in FIG. 5G, the metal layer 318 is formed in the openings 306, 314.

The present disclosure in various embodiments provides a semiconductor package 100 including a bonding layer 304 and a metal layer 318 disposed in the bonding layer 304. The metal layer 318 may include a top portion and a bottom portion. The one or more layers 308, 316 disposed adjacent the top portion of the metal layer 318 have a combined thickness greater than a thickness of the barrier layer 316 disposed adjacent the bottom portion of the metal layer 318. Some embodiments may achieve advantages. For example, the greater combined thickness of the layers 308, 316 adjacent the top portion can lead to void-free metal layer 318 during an ECP process to form the metal layer 318. The void-free metal layer 318 has reduced electrical resistance.

An embodiment is a method. The method includes depositing a bonding layer, forming a first opening in the bonding layer, depositing a conductive layer on exposed surfaces of the first opening, and forming a second opening extending from a bottom of the first opening. The second opening has a smaller dimension than a dimension of the first opening. The method further includes depositing a barrier layer on exposed surfaces of the first opening and the second opening and performing an electrochemical plating process to fill the first opening and the second opening with a metal layer.

Another embodiment is a method. The method includes depositing a bonding layer and forming a first opening extending partially through the bonding layer. A first portion of the bonding layer is exposed in the first opening. The method further includes forming a second opening through the bonding layer, and a second portion of the bonding layer is exposed in the second opening. The method further includes forming a blocking layer on the exposed second portion of the bonding layer, selectively depositing a conductive layer on the first portion of the bonding layer, removing the blocking layer, depositing a barrier layer on the conductive layer and the second portion of the bonding layer, and forming a metal layer in the first and second openings.

A further embodiment is a semiconductor package. The semiconductor package includes a first bonding layer disposed over a redistribution layer and a metal layer disposed in the first bonding layer. The metal layer includes a bond pad metal and a bond pad via. The semiconductor package further includes a barrier layer disposed adjacent the metal layer, the barrier layer includes a first portion disposed adjacent the bond pad metal and a second portion disposed adjacent the bond pad via, and the first bonding layer is disposed adjacent the second portion of the barrier layer. The semiconductor package further includes a conductive layer disposed adjacent the first portion of the barrier layer, and the first bonding layer is disposed adjacent the conductive layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
depositing a bonding layer;
forming a first opening in the bonding layer;
depositing a conductive layer on exposed surfaces of the first opening;
forming a second opening extending from a bottom of the first opening, wherein the second opening has a smaller dimension than a dimension of the first opening;
depositing a barrier layer on exposed surfaces of the first opening and the second opening; and
performing an electrochemical plating process to fill the first opening and the second opening with a metal layer.

2. The method according to claim 1, wherein the bonding layer is formed over a semiconductor die or a wafer and aligned with a redistribution layer formed over a substrate of the semiconductor die or wafer, and the substrate includes a plurality of devices formed therein.

3. The method according to claim 2, further comprising bonding the bonding layer and another bonding layer formed on another semiconductor die or wafer.

4. The method according to claim 1, wherein the conductive layer and the barrier layer comprise different materials.

5. The method according to claim 4, wherein the conductive layer comprises Ti, and the barrier layer comprises Ta or TaN.

6. The method according to claim 1, wherein the barrier layer is deposited on the conductive layer in the first opening, and the barrier layer and the conductive layer have a combined thickness.

7. The method according to claim 6, wherein the combined thickness is less than a height of the second opening.

8. A method, comprising:
depositing a bonding layer;
forming a first opening extending partially through the bonding layer, wherein a first portion of the bonding layer is exposed in the first opening;
forming a second opening through the bonding layer, wherein a second portion of the bonding layer is exposed in the second opening;
forming a blocking layer on the exposed second portion of the bonding layer;
selectively depositing a conductive layer on the first portion of the bonding layer;
removing the blocking layer;
depositing a barrier layer on the conductive layer and the second portion of the bonding layer; and
forming a metal layer in the first and second openings.

9. The method according to claim 8, wherein a redistribution layer is exposed in the second opening.

10. The method according to claim 9, wherein the blocking layer is formed on the redistribution layer.

11. The method according to claim 10, wherein the barrier layer is deposited on the redistribution layer.

12. The method according to claim 8, wherein the conductive layer and the barrier layer are conformal layers.

13. The method according to claim 8, wherein the metal layer is formed by an electrochemical plating process.

14. The method according to claim 8, wherein the conductive layer and the barrier layer comprises different materials.

15. The method according to claim 8, wherein the conductive layer and the barrier layer comprises a same material.

16. A semiconductor package, comprising:
a first bonding layer disposed over a redistribution layer;
a metal layer disposed in the first bonding layer, wherein the metal layer comprises a bond pad metal and a bond pad via;
a barrier layer disposed adjacent the metal layer, wherein the barrier layer comprises a first portion disposed adjacent the bond pad metal and a second portion disposed adjacent the bond pad via, and the first bonding layer is disposed adjacent the second portion of the barrier layer; and
a conductive layer disposed adjacent the first portion of the barrier layer, wherein the first bonding layer is disposed adjacent the conductive layer.

17. The semiconductor package according to claim 16, wherein the barrier layer and the conductive layer comprises different materials.

18. The semiconductor package according to claim 16, wherein the barrier layer and the conductive layer comprises a same material.

19. The semiconductor package according to claim 16, wherein the barrier layer further comprise a third portion disposed on the redistribution layer.

20. The semiconductor package according to claim 17, further comprising a second bonding layer bonded to the first bonding layer.
